(19) United States
(12) Patent Application Publication
(10) Pub. No.: US 2007/0124648 A1
(43) Pub. Date: May 31, 2007

(54) DATA PROTECTION METHOD

(76) Inventors: Ajay Dholakia, Apex, NC (US); Evangelos S. Eleftheriou, Zurich (CH); Xiaoyu Hu, Winterthur (CH); Ilias Iliadis, Rueschlikon (CH)

Correspondence Address: Ido Tuchman, 82-70 Beverly Road, Kew Gardens, NY, 11415, US

(21) Appl. No.: 11/554,588

(22) Filed: Oct. 31, 2006

(30) Foreign Application Priority Data
Oct. 31, 2005 (EP) 05023797.3

(51) Int. Cl. G11C 29/00

(52) U.S. Cl. 714/763

(57) ABSTRACT

One embodiment disclosed is method for protecting data stored on at least one storage unit against uncorrectable media errors. The method includes associating a given redundancy set of at least one redundancy information sector (R) with a given data set of at least two data information sectors (D). The information content of the redundancy set is computed dependent on the information content of the data set. A storing operation stores the information content of the redundancy set consecutively with the information content of the data set forming a segment such that the redundancy set is placed logically in between a first part and a second part of the data set, and accessing at least one data information sector (D) in the data set by reading and/or writing the information content of the at least one data information sector (D) and at least one redundancy information sector (R) in the redundancy set with a single request.

### CROSS-REFERENCE TO RELATED APPLICATIONS

This application claims priority under 35 U.S.C. §119 to European Patent Application No. 05023797.3 filed Oct. 31, 2005, the entire text of which is specifically incorporated by reference herein.

### BACKGROUND OF THE INVENTION

The present invention relates to a method for protecting data stored on a storage unit against uncorrectable media errors. It also extends to a device, a system, a computer program product and a computer program for protecting data stored on a storage unit against uncorrectable media errors.

A storage unit is, for example, based on at least one magnetic disk or optical disk or on solid state memory, as a storage medium. As the storage capacity of individual storage units grows, the probability of encountering at least one media-related error while reading data stored on a storage medium of a storage unit also increases. Data is lost when the error cannot be corrected by re-reading the specific part of the medium. Reliability of systems comprising two or more storage units can be increased by storing redundant data distributed to the two or more storage units. Such systems are known as redundant array of independent disks (RAID). A RAID configured system primarily protects against data loss due to a complete failure of a storage unit.

US 2005/0108594 A1 appears to disclose a method to protect data on a disk drive against uncorrectable media errors. The protection against uncorrectable media errors is provided for a RAID configured storage system by a technique in which redundancy information sectors are associated with data information sectors. The data information sectors and the redundancy information sectors are written as a single segment on a single storage unit. The redundancy information is either based on a Reed-Solomon code, an XOR-based code or one-dimensional parity.

Accordingly, it is desirable to be able to protect data stored on a storage unit against uncorrectable media errors in a manner that is more efficient and/or more reliable.

### BRIEF SUMMARY OF THE INVENTION

According to an embodiment of a first aspect of the invention, there is provided a method for protecting data stored on at least one storage unit against uncorrectable media errors comprising the steps of: associating a given redundancy set of at least one redundancy information sector with a given data set of at least two data information sectors, the information content of the redundancy set being computed dependent on the information content of the data set; storing the information content of the redundancy set consecutively with the information content of the data set forming a segment such that the redundancy set is placed logically in between a first part and a second part of the data set, and accessing at least one data information sector in the data set by reading and/or writing the information content of the at least one data information sector and at least one redundancy information sector in the redundancy set with a single request.

The present embodiment enables a more time-efficient access to data stored on the at least one storage unit because the respective data information sector and redundancy information sector are located aside each other in the segment and can therefore be read or written with the same request. The average number of sectors requested for reading or writing is reduced compared to having to read or write all sectors of the segment. Furthermore, providing intra-disk redundancy in the form of the redundancy information sectors that enable error correction of defective sectors due to media errors increases the reliability of storage units to which the present embodiment is applied.

According to a preferred embodiment of the first aspect of the present invention, the first part and the second part of the data set are of approximately equal size. This feature enables to further increase the read/write performance because the average number of requested sectors is reduced by effectively placing the redundancy set in the middle of the segment.

According to a further preferred embodiment of the first aspect of the present invention, the respective information content of each redundancy information sector in the redundancy set is computed as exclusive-or of the respective information content of a respectively associated subset of the data set. This feature enables an implementation of a reduced complexity, a higher read/write performance and reduces the need for a complex computing engine for computing the information content of the redundancy set.

In this respect, it is advantageous if the respectively associated subset of the data set for computing the information content of each redundancy information sector in the redundancy set is determined by an interleaved parity check code. This feature enables to recover as many consecutive defective sectors as there are redundancy information sectors in the redundancy set. By this, the reliability is further increased.

Alternatively, it is advantageous if the respectively associated subset of the data set for computing the information content of each redundancy information sector in the redundancy set is determined by one of Hamming code and an extended Hamming code. This feature also enables to recover as many consecutive defective sectors as there are redundancy information sectors in the redundancy set. A further advantage is that the Hamming code or the extended Hamming code exhibits a higher minimum Hamming distance than the interleaved parity check code. By this, the reliability is even further increased.

In this respect, it is further advantageous if a parity-check matrix representing one of the Hamming code and extended Hamming code has the least possible number of non-zero elements for a given Hamming distance, number of data information sectors and number of redundancy information sectors. This feature enables a reduction of the number of exclusive-or operations and thus results in time-efficiency.

According to an embodiment of a second aspect of the present invention, there is provided a device for protecting data stored on at least one storage unit against uncorrectable media errors, which corresponds to an embodiment of the first aspect of the present invention and embraces the advantages thereof.

According to an embodiment of a third aspect of the invention, there is provided a system for protecting data stored on at least one storage unit against uncorrectable media errors that comprises a device embodying the second aspect of the present invention and at least one storage unit. The system exhibits the same advantages and preferred embodiments and also the respective advantages of the preferred embodiments of a device embodying the second aspect of the invention.

In this respect, it is advantageous if the system is configured as a redundant array of independent storage units. The configuration is also known as a redundant array of independent disks (RAID).

This feature enables an increased reliability, specifically in case of a complete failure of one storage unit. The data is thus protected by inter-disk redundancy provided by the redundant array of independent storage units and the intra-disk redundancy provided by the redundancy set. An embodiment of the third aspect of the present invention is not limited to disks and also may comprise any other kind of storage unit.

According to an embodiment of a fourth aspect of the present invention, there is provided a computer program product comprising a computer-readable medium embodying program instructions executable by a computer, which corresponds to an embodiment of the first aspect of the present invention and the advantages thereof.

According to an embodiment of a fifth aspect of the present invention, there is provided a computer program for protecting data stored on at least one storage unit against uncorrectable media errors comprising program instructions. The program instructions correspond to an embodiment of the first aspect of the present invention and the advantages thereof.

### BRIEF DESCRIPTION OF THE SEVERAL VIEWS OF THE DRAWINGS

Reference will now be made, by way of example, to the accompanying drawings, in which:

FIG. 1 schematically illustrates a system embodying the present invention;

FIG. 2 is an overview of data organization in a RAID level 5 configured system comprising five storage units;

FIG. 3 is an overview of data organization in one segment of a RAID level 5 comprising eight storage units;

FIG. 4 shows a parity check matrix representing an interleaved parity check code;

FIG. 5A shows a parity check matrix representing a known extended Hamming code;

FIG. 5B shows a parity check matrix of a sparse extended Hamming code;

FIG. 5C shows a parity check matrix of a sparse Hamming code;

FIG. 6 is a general overview of data organization of one segment, and

FIG. 7 is a flow chart of a method for protecting data against uncorrectable media errors.

### DETAILED DESCRIPTION OF THE INVENTION

In the following, a description will be provided of the present invention through an embodiment of the present invention. However, the following embodiments do not restrict the invention in the scope of the invention and all combinations of features explained in the embodiment are not always essential to means of the invention for solving the problems.

As will be appreciated by one skilled in the art, the present invention may be embodied as a method, system, or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, or a magnetic storage device.

Computer program code for carrying out operations of the present invention may be written in an object oriented programming language such as Java, Smalltalk, C++ or the like. However, the computer program code for carrying out operations of the present invention may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN) or a wide area network (WAN), or the connection may be made to an external computer (for example, through the Internet using an Internet Service Provider).

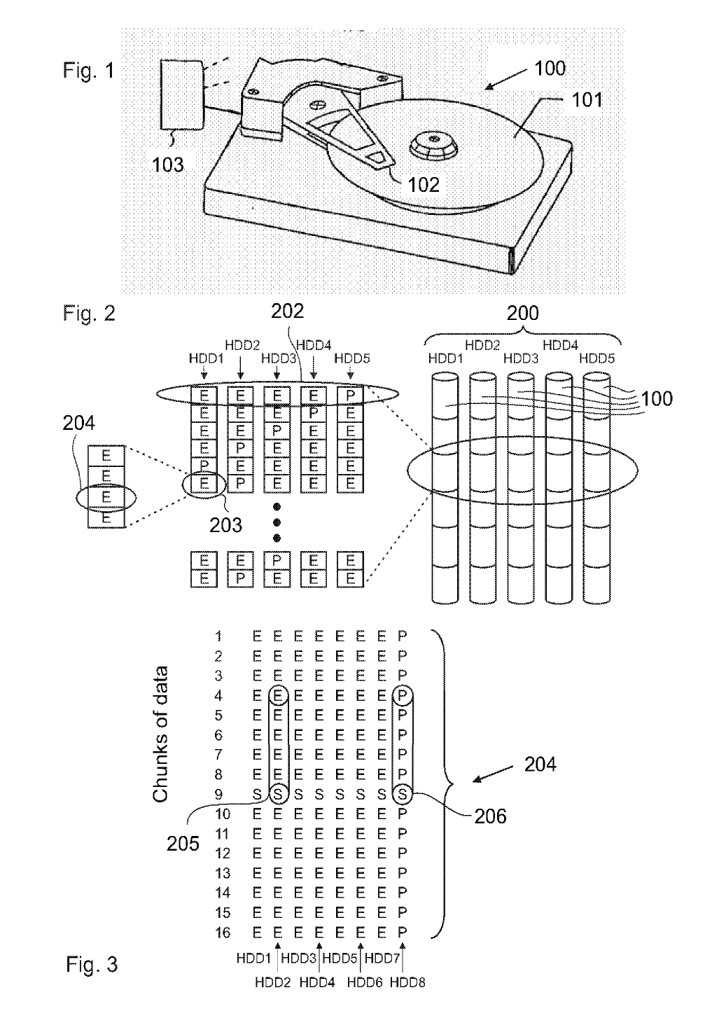

FIG. 1 shows a system embodying the present invention for protecting data stored on a storage unit 100 against uncorrectable media errors. The storage unit 100 is, in the present case, represented by a hard disk drive comprising one magnetic disk 101 as storage medium and a read/write head 102. The read/write head 102 can be positioned over a selected track on the magnetic disk 101. Binary data is stored on the magnetic disk 101 by selectively orienting magnetization in selected data fields on the magnetic disk 101 with the read/write head 102. The system further comprises a data protection unit 103 for protecting data stored on the storage unit 100 against uncorrectable media errors. The storage unit 100 is coupled with the data protection unit 103.

The following can be appreciated in relation to the above-described case: the storage unit 100 may comprise more than one magnetic disk 101 and the storage medium is not limited to a magnetic disk-type 101 and may be any other type of storage medium or combination of different types of storage medium.

FIG. 2 is an overview of data organization in a RAID level 5 configured system comprising an array 200 of five storage units 100 that are labeled as a first storage unit HDD1, a second storage unit HDD2, a third storage unit HDD3, a fourth storage unit HDD4, and a fifth storage unit HDD5. The five storage units 100 are respectively coupled with the data protection unit 103 as shown in FIG. 1.

Data is organized in stripes 202. The stripes 202 span all five storage units 100. Each individual storage unit 100 of the system comprises one strip 203 for each stripe 202. Each strip 203 comprises four segments 204 and each segment 204 comprises sixteen chunks of data, each comprising eight sectors. Each segment 204 therefore has 128 sectors.

In the RAID level 5 configured system shown in FIG. 2, each strip 203 carries either user data E or RAID parity data P. The RAID parity data P is computed as modulo 2 sum, also known as exclusive-or or XOR, of all user data E in the same stripe 202. The location of the RAID parity data P is respectively set to be different in the storage units 100 of the array 200 in successive stripes. For example, it can be seen from FIG. 2, that the RAID parity data P location in each stripe 202 is chosen so as to form a diagonal pattern across the stripes 202 in the array 200. If one of the storage units 100 fails, the respective user data E and RAID parity data P stored on the failed storage unit 100 can be recovered from the other user data E and RAID parity data P stored in the same stripe on the other storage units 100 that are still working. A RAID level 5 configured system allows rebuilding of the information content of one failed storage unit 100 by recovering the lost data and writing it on a spare storage unit 100 included in the system.

Before the reconstruction is finished, data loss will unavoidably happen in a RAID level 5 configured system if either a second storage unit 100 fails or a media error occurs on one of the other storage units 100. As the storage capacity of individual storage units 100 grows, the total number of bytes that are read during a rebuild operation becomes larger. This increases the probability of encountering an uncorrectable media error, typically resulting in one or more sectors becoming unreadable. The occurrence of uncorrectable media errors is particularly problematic when combined with a failure of one storage unit 100 in the system. For example, if one storage unit 100 fails in a RAID level 5 configured system, the rebuild process must read all the data on the remaining storage units 100 in order to rebuild the lost data on the spare storage unit 100. During this phase, an uncorrectable media error on any of the still working storage units 100 in the array 200 would lead to data loss because there is no way to reconstruct the information content of the uncorrectable sectors. The risk of data loss in this vulnerable phase becomes worse due to the continuous rapid increase of disk capacity and much slower advance in disk bandwidth and disk reliability. Theoretical and field results have shown that the main source of data loss in RAID level 5 configured systems is media-related failure during rebuilding.

The risk of data loss due to one or more media errors can be reduced by providing intra-disk redundancy, also called Sector Protection through Intra-Disk REdundancy (SPIDRE). FIG. 3 is an overview of data organization of one segment 204 of a further RAID level 5 configured system comprising eight storage units 100 labeled as the first storage unit HDD1, the second storage unit HDD2, the third storage unit HDD3, the fourth storage unit HDD4, the fifth storage unit HDD5, a sixth storage unit HDD6, a seventh storage unit HDD7, and an eighth storage unit HDD8. The segment 204 comprises sixteen chunks of data on each of the storage units 100 that either carry user data E, RAID parity data P or intra-disk redundancy data S. Each segment 204 on each storage unit 100 has one chunk of data carrying intra-disk redundancy data S. The intra-disk redundancy data S respectively is associated to the user data E or RAID parity data P of segment 204 on the same storage unit 100.

The concept of intra-disk redundancy can be applied to any of the existing RAID architectures or levels, e.g. RAID level 5, level 51, level 6 or level N+3. RAID redundancy provided by the RAID redundancy data P primarily protects data stored on the array 200 against data loss due to the failure of one complete storage unit 100. The intra-disk redundancy protects data stored on each individual storage unit 100 against data loss due to uncorrectable media errors. As can be appreciated, the concept of intra-disk redundancy can also be applied to a system comprising only one single storage unit 100.

Every change of user data E in segment 204, e.g. the fourth chunk of data of segment 204 on the second storage unit HDD2, requires the update of the intra-disk redundancy data S associated to the changed user data E in the same segment 204, e.g. the ninth chunk of data of segment 204 on the second storage unit HDD2. Further, the RAID parity data P corresponding to the changed user data E must be updated, e.g. the fourth chunk of data of segment 204 on the eighth storage unit HDD8. Due to the update of the RAID parity data P, the intra-disk redundancy data S associated to the updated RAID parity data P must also be updated, e.g. the ninth chunk of data of segment 204 on the eighth storage unit HDD8. Writing these four chunks of data individually would lead to four requests. By storing the intra-disk redundancy data S consecutively with the user data E in the same segment 204, only a first request 205 and a second request 206 is used to update the chunk of user data E, the chunk of RAID parity data P and the respective corresponding chunks of intra-disk redundancy data S.

In normal operation, i.e. without failure of a storage unit 100, user data E can be read from the storage unit 100 without also reading the corresponding RAID parity data P. Accordingly, user data E can be read from the storage unit 100 without also reading intra-disk redundancy data S as long as no media error occurs while reading the user data E. Reading of several consecutive chunks of user data E is advantageously done with a single request. This request may also comprise reading the intra-disk redundancy data S if it is located between chunks of user data E covered by the request. As can be appreciated, the information content of the intra-disk redundancy data S can be ignored in this case.

Each request for updating user data E uses the reading and writing of at least two chunks of data on at least two storage units 100: the changed user data E and RAID parity data P, respectively, and the respectively corresponding intra-disk redundancy data S. Reading and writing each of the four chunks of data with an individual request would use four requests for reading plus four requests for writing for each update of user data E. By applying the first request 205 and the second request 206, updating of user data E is achieved with only two requests for reading plus two requests for writing. One or more additional chunks of data, particularly user data E or RAID parity data P, that are logically placed in-between the changed chunk of user data E or RAID parity data P and the corresponding chunk of intra-disk redundancy data S may be read and written with the same request, respectively. The requested number of chunks of data for each request therefore depends on the distance between the changed chunk of user data E or RAID parity data P and the corresponding chunk of intra-disk redundancy data S. The average number of chunks of data of all requests for reading and/or writing are reduced by placing the intra-disk redundancy data S approximately in the middle of segment 204 compared to placing it at the beginning or the end of segment 204. In the present embodiment, the average number of chunks of data read and/or written per request is about 5.27. A typical ratio of seek time for each request to the time used to read one chunk of data of, for example, 4 KB, is about 50 to 1. The effect of reading and/or writing more than one chunk of data with each request on the overall read/write performance, particularly when updating user data E, is therefore smaller compared to accessing each of the four chunks of data of the above example for updating user data E, RAID parity data P and intra-disk redundancy data S with individual requests.

As an example, each chunk of data has a size of 4 KB. Segment 204 has 128 sectors. Each chunk of data is divided into eight sectors. The chunk of data carrying the intra-disk redundancy data S is considered as a redundancy set of redundancy information sectors R. A number r of redundancy information sectors R is 8. Each chunk of user data E has eight data information sectors D. There are fifteen chunks of user data E in segment 204. A number n of data information sectors D carrying user data E therefore is 120. All 120 data information sectors D of all chunks of user data E of segment 204 are considered a data set. The redundancy set is associated with the data set in segment 204. The information content of the redundancy set is computed dependent on the information content of the data set. Particularly, the redundancy information sectors R in the redundancy set each can be considered as a parity that is computed dependent on a respectively associated subset of the data set, i.e. each redundancy information sector R is computed as parity of a respectively associated set of data information sectors D that is a subset of the data set.

In case a chunk of user data E cannot be read correctly from storage unit 100, this chunk of user data E is marked as a so-called “erasure”. The information content of the erasure can in some cases be recovered using the information content of other chunks of user data E and the intra-disk redundancy data S of the same segment 204. The error correction capability, or more precisely, the erasure recovery capability achieved by providing the redundancy set that is associated with the data set in segment 204 depends on the respective selection of data information sectors D that are used for computing the respective redundancy information sector R. It is desirable to compute the information content of the redundancy set with as few computing operations as possible so as to reduce the need to use a complex computing engine to perform this task. The computing engine is part of data protection unit 103.

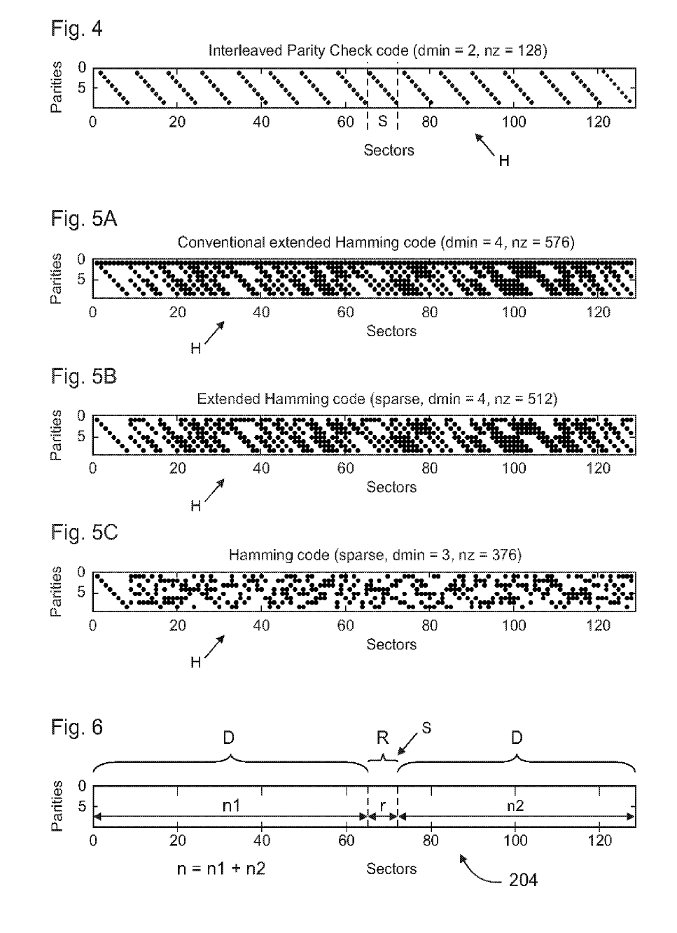

FIG. 4 shows a parity check matrix H that represents a so-called interleaved parity check code (IPC code), particularly an IPC-8 (128, 120) code, which is used in an embodiment of the present invention in order to calculate a respective redundancy information sector R. The parity check matrix H has eight rows, one for each redundancy information sector R in the redundancy set. The parity check matrix H further has 128 columns, one for each sector of segment 204. Non-zero elements in the parity check matrix H are shown as dots. The interleaved parity check code has eight non-zero elements for each chunk of data. The non-zero elements are placed on the main diagonal of each eight by eight sub-matrix representing one chunk of data. All non-zero elements in each row of the parity check matrix H mark all sectors that form the respectively associated subset of the data set used for computing the respective redundancy information sector R. The respective redundancy information sector R is computed by computing the exclusive-or of all data information sectors D marked in the respective row of the parity check matrix H. Applying the interleaved parity check code, there is a number nz of non-zero elements of 128, i.e. 128 exclusive-or computations must be performed for computing the information content of the redundancy set, i.e. the intra-disk redundancy data S for segment 204. The interleaved parity check code has a minimum Hamming distance dmin of 2. The IPC-8 (128,120) code has the property of correcting up to the number r of redundancy information sectors R, i.e. up to eight, consecutive sectors with a media error and any single one sector media error in segment 204.

FIGS. 5A to 5C show alternative parity check matrices H that can be used in an embodiment of the present invention. The parity check matrix H (second type) shown in FIG. 5A is a known extended Hamming code with a minimum Hamming distance dmin of 4. The number nz of non-zero elements in this parity check matrix H is 576. The parity check matrix H shown in FIG. 5B (third type) is an extended Hamming code with the parity check matrix H being sparse, i.e. having a reduced number nz of non-zero elements of 512. The minimum Hamming distance dmin is 4. In the parity check matrix H shown in FIG. 5C (fourth type), the number nz of non-zero elements is further reduced and the Hamming code is sparse with the minimum Hamming distance dmin being 3. The number nz of non-zero elements is 376.

Both the third and fourth types of the parity check matrix H have the least number nz of non-zero elements for the given minimum Hamming distance dmin of 4 or 3, respectively, and for the number r of redundancy information sectors R of 8 and the number n of data information sectors D of 120. The third and the fourth types of the parity check matrix H are also modified such that they show the same properties regarding the error correction capability of correcting up to the number r of redundancy information sectors R, i.e. up to eight, consecutive sectors with a media error as the interleaved parity check code. In comparison to the interleaved parity check code, the extended Hamming code has the advantage of a better error correction capability due to the minimum Hamming distance dmin values of 4 or 3, respectively. This additionally enables correcting any three and two sector media errors in segment 204, respectively. In general, the minimum Hamming distance dmin minus one single media errors can be corrected in segment 204. Using the extended Hamming code thus leads to a better data protection on storage unit 100 and therefore to a higher reliability of the storage unit 100 but also requires increased computing power for performing the higher number of exclusive-or operations due to the higher number nz of non-zero elements in the parity check matrix H compared to the interleaved parity check code. Error correction capability of the interleaved parity check code can be applied to most high-end storage units 100, particularly for most high-end hard disk drives (such as, for example, incorporating small computer system interfaces, SCSI). One of the extended Hamming codes with a relatively higher error correction capability may be considered for low-end storage units 100, particularly for low-end hard disk drives (such as, for example, incorporating, advanced technology attachment systems, ATA, or serial advanced technology attachment systems, SATA).

FIG. 6 shows a more general overview of data organization in each segment 204 of storage unit 100. The number r of redundancy information sectors R are placed logically in-between a first part with a number n1 of data information sectors D and a second part with a number n2 of data information sectors D of the data set. The number n of data information sectors D in the data set is therefore equal to the sum of the number n1 of data information sectors D of the first part and the number n2 of data information sectors D of the second part of the data set. Preferably, the number n1 of data information sectors D of the first part and the number n2 of data information sectors D of the second part of the data set are approximately equal. It may be advantageous, though, to observe the boundaries of the chunks of data for access to be performed in a time-efficient and uncomplicated manner and thus having slightly differing numbers n1 and n2 of data information sectors D. In the present embodiment, the number r of redundancy information sectors R is eight, the number n1 of data information sectors D of the first part of the data set is 64 and the number n2 of data information sectors D of the second part of the data set is 56.

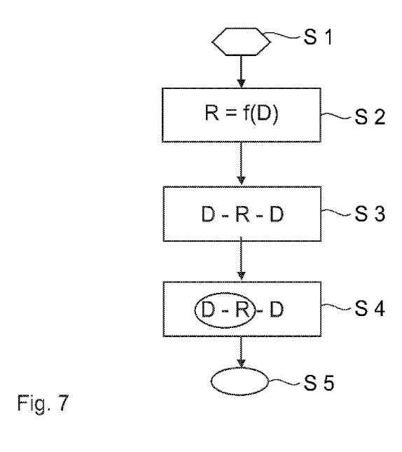

FIG. 7 shows a flow chart of a method for protecting data stored on a one storage unit 100 against uncorrectable media errors that may be implemented in hardware in the data protection unit 103. The method also can be implemented as a computer program comprising program instructions that can be performed by a computer. The data protection unit 103 may comprise a computer for performing the program instructions of the computer program. The computer program may be part of an operating system or of a basic input/output system of the computer.

The method begins with a step S1 as an entry point. In a step S2, the redundancy set that comprises at least one redundancy information sector R is associated with the data set that comprises at least two data information sectors D. The information content of the redundancy set is computed dependent on the information content of the data set. In a step S3, storage of the information content of the redundancy set and the information content of the data set is caused. The information content of the redundancy set and the information content of the data set are stored consecutively to form segment 204. The redundancy set is placed logically in-between the first part and the second part of the data set. In a step S4, access to at least one data information sector D in the data set is caused by reading and/or writing the information content of the at least one data information sector D and the at least one redundancy information sector R in the redundancy set with a single request. The method ends with a step S5.

The steps S2, S3, and S4 are not limited to be executed in the sequence shown in FIG. 7. For example, the actual placing of the redundancy set logically in-between the first part and the second part of the data set is executed when writing data to the segment 204, i.e. when performing step S4. Further, when the information content of one or more sectors is recovered due to an uncorrectable media error, the data is read from segment 204 in step S4. The information content of the defective sectors is recovered by using the unaffected sectors of the redundancy set and the data set. The computation of the information content of the defective sectors may be performed similar to the computation of the information content of the redundancy set in step S2, e.g. by computing the exclusive-or of the respectively associated unaffected data information sectors D and respective redundancy information sectors R.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to embodiments thereof, it will be apparent that modifications and variations are possible without departing from the scope of the invention defined in the appended claims.

That which is claimed is:

1. A method for protecting data stored on at least one storage unit against uncorrectable media errors, the method comprising:
associating a given redundancy set of at least one redundancy information sector with a given data set of at least two data information sectors, the information content of the redundancy set being computed dependent on the information content of the data set;
storing the information content of the redundancy set consecutively with the information content of the data set forming a segment such that the redundancy set is placed logically in between a first part and a second part of the data set, and
accessing at least one data information sector in the data set by reading and/or writing the information content of the at least one data information sector and at least one redundancy information sector in the redundancy set with a single request.

2. The method according to claim 1, wherein the first part and the second part of the data set are of approximately equal size.

3. The method according to claim 1, wherein the respective information content of each redundancy information sector in the redundancy set is computed as exclusive-or (XOR) of the respective information content of a respectively associated subset of the data set.

4. The method according to claim 3, wherein the respectively associated subset of the data set for computing the information content of each redundancy information sector in the redundancy set is determined by an interleaved parity-check code.

5. The method according to claim 3, wherein the respectively associated subset of the data set for computing the information content of each redundancy information sector in the redundancy set is determined by one of Hamming code and an extended Hamming code.

6. The method according to claim 5, wherein a parity-check matrix representing one of the Hamming code and extended Hamming code has the least possible number of non-zero elements for a given Hamming distance, number of data information sectors and number of redundancy information sectors.

7. A device for protecting data stored on at least one storage unit against uncorrectable media errors, the device comprising:
a data protection unit operable to:
associate a given redundancy set of at least one redundancy information sector with a given data set of at least two data information sectors, the information content of the redundancy set being computed dependent on the information content of the data set;
store the information content of the redundancy set consecutively with the information content of the data set forming a segment such that the redundancy set is placed logically in between a first part and a second part of the data set, and
access at least one data information sector in the data set by reading and/or writing the information content of the at least one data information sector and at least one redundancy information sector in the redundancy set with a single request.

8. The device according to claim 7, further comprising at least one storage unit coupled to the data protection unit.

9. The device according to claim 8, wherein the device is configured as a redundant array of independent storage units.

10. A computer program product for protecting data stored on at least one storage unit against uncorrectable media errors comprising a computer readable medium embodying program instructions executable by a computer to:
associate a given redundancy set of at least one redundancy information sector with a given data set of at least two data information sectors, the information content of the redundancy set being computed dependent on the information content of the data set;
store the information content of the redundancy set consecutively with the information content of the data set forming a segment such that the redundancy set is placed logically in between a first part and a second part of the data set, and
access at least one data information sector in the data set by reading and/or writing the information content of the at least one data information sector and at least one redundancy information sector in the redundancy set with a single request.

11. The computer program product according to claim 10, wherein the first part and the second part of the data set are of approximately equal size.

12. The computer program product according to claim 10, wherein the respective information content of each redundancy information sector in the redundancy set is computed as exclusive-or (XOR) of the respective information content of a respectively associated subset of the data set.

13. The computer program product according to claim 12, wherein the respectively associated subset of the data set for computing the information content of each redundancy information sector in the redundancy set is determined by an interleaved parity-check code.

14. The computer program product according to claim 12, wherein the respectively associated subset of the data set for computing the information content of each redundancy information sector in the redundancy set is determined by one of Hamming code and an extended Hamming code.

15. The computer program product according to claim 14, wherein a parity-check matrix representing one of the Hamming code and extended Hamming code has the least possible number of non-zero elements for a given Hamming distance, number of data information sectors and number of redundancy information sectors.
